(19) United States
(12) Patent Application Publication
(10) Pub. No.: US 2025/0263840 A1
(43) Pub. Date: Aug. 21, 2025

(54) CHEMICAL VAPOR DEPOSITION APPARATUS

(71) Applicant: SAMSUNG ELECTRONICS CO., LTD., Suwon-si (KR)

(72) Inventors: Guentae KIM, Suwon-si (KR); Jinsung KWON, Suwon-si (KR); Kysungdon HAN, Suwon-si (KR)

(73) Assignee: SAMSUNG ELECTRONICS CO., LTD., Suwon-si (KR)

(21) Appl. No.: 19/051,947

(22) Filed: Feb. 12, 2025

(30) Foreign Application Priority Data
Feb. 20, 2024 (KR) 10-2024-0024464

(51) Int. Cl. C23C 16/458

(52) U.S. Cl. CPC C23C 16/4581

(57) ABSTRACT

Provided is a chemical vapor deposition apparatus including a reaction chamber, a main disk inside the reaction chamber, a satellite disk on the main disk, a lower surface of the satellite disk including a groove that has a first thickness and a first diameter, a plate in the groove, and a fixing pin configured to penetrate the plate and connected to the main disk and the satellite disk.

### CROSS-REFERENCE TO RELATED APPLICATION

This application claims priority to Korean Patent Application No. 10-2024-0024464 filed on Feb. 20, 2024, in the Korean Intellectual Property office, the disclosure of which is incorporated by reference herein in its entirety.

### BACKGROUND

### 1. Field

Embodiments of the present disclosure relate to a chemical vapor deposition apparatus, and more particularly, to a chemical vapor deposition apparatus including a satellite disk capable of variably controlling a temperature of a substrate.

### 2. Background of Related Art

A chemical vapor deposition apparatus is used for forming a thin layer on a substrate, such as a wafer, by using a chemical reaction. In general, the chemical vapor deposition apparatus is configured to inject a reaction gas at high steam pressure into a vacuum chamber in which a substrate is prepared and to grow a thin layer on the substrate by using a chemical reaction of the reaction gas.

Recently, in accordance with the high integration and high performance of semiconductor devices, chemical vapor deposition (CVD) such as metal organic CVD (MOCVD) has been widely used. Particularly, when high efficiency/high output light emitting diodes (LEDs) are manufactured, a MOCVD apparatus may be used.

### SUMMARY

One or more embodiments provide a chemical vapor deposition apparatus including a satellite disk including grooves in a rear surface of the satellite disk.

According to an aspect of one or more embodiments, there is provided a chemical vapor deposition apparatus including a reaction chamber, a main disk inside the reaction chamber, a satellite disk on the main disk, a lower surface of the satellite disk including a groove that has a first thickness and a first diameter, a plate in the groove, and a fixing pin configured to penetrate the plate and connected to the main disk and the satellite disk.

According to another aspect of one or more embodiments, there is provided a chemical vapor deposition apparatus including a reaction chamber, a main disk in the reaction chamber and including a pocket, a satellite disk, a center portion of a lower surface of the satellite disk including a groove having a first thickness and a first diameter, the satellite disk being in the pocket, a fixing pin between the main disk to the plurality of satellite disks, and a plate including a through hole having a diameter equal to a diameter of the fixing pin, the plate being detachably inserted in the groove, wherein a second thickness of the plate is less than the first thickness and a second diameter of the plate is less than the first diameter.

According to still another aspect of one or more embodiments, there is provided a chemical vapor deposition apparatus including a reaction chamber, a main disk inside the reaction chamber and including a pocket, a satellite disk inside the pocket and configured to rotate, the satellite disk being configured to accommodate a substrate and including a groove having a first thickness and a first diameter in a lower surface of the satellite disk, a gas inlet configured to supply a reaction gas to the substrate, a support unit including a gas flow path through which a flow gas is supplied to the pocket, the gas flow path being configured to support the main disk to be rotatable, a fixing pin between the main disk and the satellite disk, and a plate penetrated by the fixing pin, and inserted into the groove, wherein a second thickness of the plate is less than the first thickness and a second diameter of the plate is less than the first diameter.

### BRIEF DESCRIPTION OF DRAWINGS

Embodiments will be more clearly understood from the following detailed description taken in conjunction with the accompanying drawings in which:

FIG. 1 is a schematic cross-sectional view of a chemical vapor deposition apparatus according to one or more embodiments;

FIG. 2 is a schematic plan view of a satellite disk of a chemical vapor deposition apparatus according to one or more embodiments;

FIG. 3 is an enlarged cross-sectional view of region EX1 in FIG. 1 according to one or more embodiments;

FIG. 4 is an enlarged cross-sectional view of region EX1 in FIG. 1 according to another embodiment; and

FIG. 5 is a table showing a temperature of a substrate with respect to a plate thickness of a chemical vapor deposition apparatus, according to one or more embodiments.

### DETAILED DESCRIPTION

Hereinafter, embodiments are described in detail with reference to the attached drawings. Embodiments described herein are example embodiments, and thus, the disclosure is not limited thereto.

It will be understood that, although the terms first, second, third, fourth, etc. may be used herein to describe various elements, components, regions, layers and/or sections (collectively “elements”), these elements should not be limited by these terms. These terms are only used to distinguish one element from another element. Thus, a first element described in this description section may be termed a second element or vice versa in the claim section without departing from the teachings of the disclosure.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

As used herein, an expression “at least one of” preceding a list of elements modifies the entire list of the elements and does not modify the individual elements of the list. For example, an expression, “at least one of a, b, and c” should be understood as including only a, only b, only c, both a and b, both a and c, both b and c, or all of a, b, and c.

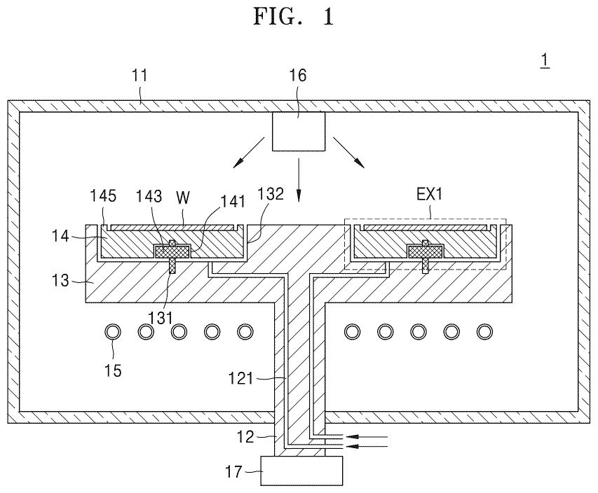

FIG. 1 is a schematic cross-sectional view of a chemical vapor deposition apparatus according to one or more embodiments.

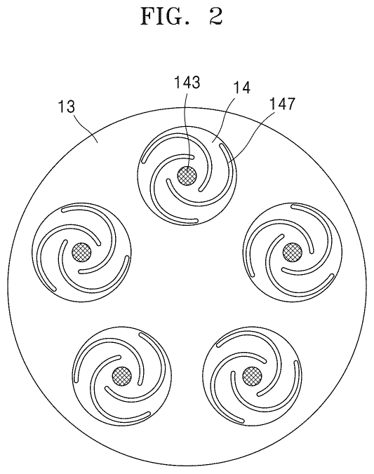

FIG. 2 is a schematic plan view of a satellite disk of the chemical vapor deposition apparatus 1 according to one or more embodiments.

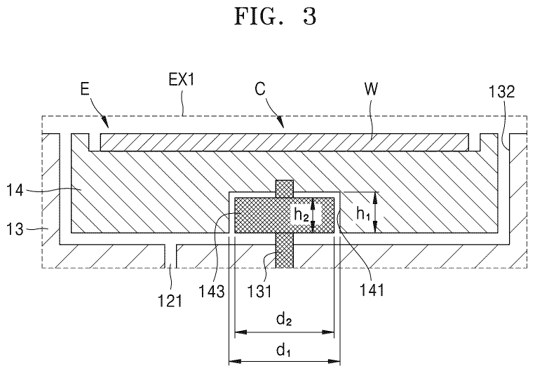

FIG. 3 is an enlarged cross-sectional view of region EX1 in FIG. 1 according to one or more embodiments.

Referring to FIGS. 1 through 3, a chemical vapor deposition apparatus 1 according to one or more embodiments may include a reaction chamber 11, a support unit 12, a main disk 13, a satellite disk 14, a heater 15, a gas inlet 16, and a driving motor 17.

In one or more embodiments, the reaction chamber 11 may include a ceiling and sidewalls, and may have a certain inner space. The main disk 13 may be arranged inside the reaction chamber 11. The main disk 13 may have a circular disk shape. In this case, the main disk 13 may include a susceptor on which a substrate W may be mounted. The substrate W may include a semiconductor wafer.

In one or more embodiments, the main disk 13 may be arranged inside the reaction chamber 11 to be rotatable by the support unit 12. The driving motor 17 may support and rotate the support unit 12. Therefore, the main disk 13 may be rotated inside the reaction chamber 11. For example, the main disk 13 may rotate clockwise or counterclockwise according to the driving of the driving motor 17 with the support unit 12 as the center axis.

In one or more embodiments, the support unit 12 may include a hollow shaft or a rod. A gas flow path 121 may be provided in the support unit 12 to supply the flow gas to a pocket 132.

In one or more embodiments, a plurality of pockets 132 may be arranged on an upper surface of the main disk 13. Each of the plurality of pockets 132 may accommodate the satellite disk 14. The plurality of pockets 132 may be formed to be recessed in a vertical direction from the upper surface of the main disk 13. Each of the plurality of pockets 132 may have substantially the same shape as the satellite disk 14 to accommodate the satellite disk 14. For example, the plurality of pockets 132 may have a cylindrical shape. In FIG. 2, the chemical vapor deposition apparatus 1 according to one or more embodiments is illustrated as including five satellite disks 14 on one main disk 13, but embodiments are not limited thereto.

In one or more embodiments, the satellite disk 14 may be arranged inside each of the plurality of pockets 132. The satellite disk 14 may be arranged to rotate inside the pocket 132. In this case, the satellite disk 14 and the main disk 13 may be connected to each other by using a fixing pin 131. The fixing pin 131 may be connected to a lower center of the satellite disk 14. The satellite disk 14 may rotate in a clockwise or counterclockwise direction with the fixing pin 131 as a center axis. In addition, the fixing pin 131 may be arranged so that the satellite disk 14 is spaced apart from a lower surface of the pocket 132 by a certain height in a vertical direction.

In one or more embodiments, the gas flow path 121 may be arranged inside the main disk 13 and the support unit 12. The gas flow path 121 may supply the flow gas from the gas supply means to the pocket 132. A plurality of spiral grooves 147 may be arranged on the lower surface of the pocket 132. The plurality of spiral grooves 147 may have a spiral shape. The flow gas discharged from the gas flow path 121 through the plurality of spiral grooves 147 may rotate in a certain direction. The satellite disk 14 may rotate according to the flow gas proceeding through the plurality of spiral grooves 147. In addition, the satellite disk 14 may be spaced apart from the lower surface of the pocket 132 by a certain height in the vertical direction and rotate by the flow gas. In this case, nitrogen, water, or the like may be used as the flow gas, but embodiments are not limited thereto. In addition, the rotation of the satellite disk 14 may be controlled by adjusting the flow rate of the flow gas.

In one or more embodiments, a deposition target such as the substrate W may be arranged on the satellite disk 14. In this case, a fixing ring 145 may be arranged at an edge of the satellite disk 14 so that the substrate W does not move. The fixing ring 145 may be arranged on the satellite disk 14 to surround the edge of the substrate W seated on the satellite disk 14. The fixing ring 145 may fix the substrate W seated on the satellite disk 14. In this case, the fixing ring 145 may have an annular shape, but embodiments are not limited thereto. The fixing ring 145 may have various shapes according to the shape of the satellite disk 14. The fixing ring 145 may be integrally formed with the satellite disk 14, but embodiments are not limited thereto.

In one or more embodiments, the heater 15 may be arranged below the main disk 13. The heater 15 may heat the main disk 13 to a certain temperature. The heater 15 may heat the main disk 13 from several hundred degrees in centigrade to a temperature greater than or equal to about 1000° C. For example, when a gallium nitride (GaN)-based growth layer is formed, the heater 15 may heat the main disk 13 to about 700° C. to about 1300° C. The heater 15 may include a coil to which a high frequency current is applied, and in this case, the main disk 13 may be heated in an induction heating method. In one or more other embodiments, the heater 15 may include a conductive wire which generates resistance heat.

The main disk 13 and the satellite disk 14 may transfer heat from the heater 15 to the substrate W arranged on the satellite disk 14. Accordingly, the main disk 13 and the satellite disk 14 may be formed of a material having durability capable of withstanding a heating temperature generated by the heater 15. For example, the main disk 13 and the satellite disk 14 may be formed of graphite. To enhance durability, a hardness reinforcement coating layer, for example, a silicon carbide (SiC) coating layer may be formed on the main disk 13 and the satellite disk 14.

In one or more embodiments, the gas inlet 16 may include a device supplying the reaction gas to be deposited on the substrate W. The reaction gas may include a source gas and a carrier gas. The gas inlet 16 may be attached to an upper portion of the reaction chamber 11 to supply the reaction gas into the reaction chamber 11 via a nozzle.

In one or more embodiments, the substrate W may maintain a relatively high temperature by using the main disk 13 heated to a relatively high temperature, and the reaction gas may contact an upper surface of the substrate W to perform a chemical deposition reaction. For example, a chemical deposition reaction may be performed on the upper surface of the substrate W to deposit and grow a growth layer such as a GaN-based growth layer.

Only a portion of the reaction gas supplied into the reaction chamber 11 may be used to deposit a growth layer on the substrate W, and the remainder of the reaction gas may be discharged from the reaction chamber 11. In addition, the flow gas may also be discharged from the reaction chamber 11 after being used to rotate the satellite disk 14. The reaction gas and the flow gas may be discharged from the inside of the reaction chamber 11 via a gas discharging unit.

Warpage may occur in a substrate and a growth layer in a conventional chemical vapor deposition apparatus due to differences in a lattice constant and a thermal expansion rate between the substrate and the layer growing on the substrate. Due to the warpage, a temperature non-uniformity may occur on a surface of the substrate, accordingly, the composition of the growth layer growing thereon may become non-uniform, and as a result, non-uniformity in a thickness and wavelength of the growth layer may increase. The non-uniformly grown growth layer may cause a light emitting wavelength and electrical characteristics of a semiconductor light emitting device including the non-uniformly grown growth layer become non-uniform, and a decrease in quality, performance, and yield may occur.

In one or more embodiments, the satellite disk 14 of the chemical vapor deposition apparatus 1 according to one or more embodiments may include a groove 141. The groove 141 may be arranged in the center portion of a lower surface of the satellite disk 14. The groove 141 may be arranged on the lower surface of the satellite disk 14, and may be arranged in the center portion of the satellite disk 14 to be concentric with the satellite disk 14. For example, the groove 141 may have a cylindrical shape, and in this case, the groove 141 may have a first thickness h₁ and a first diameter d₁. However, the shape of the groove 141 is not limited thereto, and may be variously designed as necessary. In this case, the first thickness h₁ may be designed to be less than a thickness of the satellite disk 14 in the vertical direction. For example, the first thickness h₁ may be in a range of about 0.45 mm to about 1 mm. In this case, the first diameter d₁ may be designed to be less than the diameter of the satellite disk 14 in a horizontal direction perpendicular to the vertical direction. For example, the first diameter d₁ may be less than about 40 mm.

In one or more embodiments, each of the plurality of satellite disks 14 may include the groove 141. In this case, the diameters or thicknesses of the grooves 141 included in the different satellite disks 14 from each other may be the same. However, the embodiments are not limited thereto, and the diameters or thicknesses of the grooves 141 included in the different satellite disks 14 from each other may also be different.

In one or more embodiments, the chemical vapor deposition apparatus 1 according to one or more embodiments may further include a plate 143. The plate 143 may be arranged to be inserted into the groove 141. The plate 143 may include a through hole, and the fixing pin 131 may penetrate the through hole. The fixing pin 131 may fix the plate 143 to be seated inside the groove 141 of the satellite disk 14. In this case, the diameter of the through hole and the diameter of the fixing pin 131 may be the same. For example, the diameter of the through hole and the diameter of the fixing pin 131 may be about 2.5 mm.

In one or more embodiments, the plate 143 may have a second thickness h₂ and a second diameter d₂. In this case, the second thickness h₂ may be less than the first thickness h₁. For example, the second thickness h₂ may be about 0.2 mm to about 0.4 mm, but embodiments are not limited thereto. In addition, the second diameter d₂ may be less than the first diameter d₁. For example, the second diameter d₂ may be about 38 mm, but embodiments are not limited thereto. Because the second thickness h₂ and the second diameter d₂ of the plate 143 are less than the first thickness h₁ and the first diameter d1 of the groove 141, respectively, a certain space may be formed between the plate 143 and the groove 141.

In one or more embodiments, the plate 143 may include a material having high thermal conductivity. For example, the plate 143 may include silicon carbide (SiC), but embodiments are not limited thereto.

The chemical vapor deposition apparatus 1 according to one or more embodiments may compensate for the temperature of the center C of the substrate W, by forming a groove 141 at the center of the lower surface of the satellite disk 14 and inserting and arranging the plate 143 into the groove 141. By compensating for the temperature of the center C of the substrate W, the non-uniformity in the thickness and wavelength of the growth layer grown on the substrate W may be reduced, and thus, by making the light emitting wavelength and electrical characteristics of the light emitting device uniform, the quality, performance, and yield of the substrate W may be increased.

The chemical vapor deposition apparatus 1 according to one or more embodiments may variably control the temperature of the substrate W, by variously controlling the plate 143 inserted into and arranged in the groove 141. In particular, by inserting and arranging the plate 143 having different sizes and physical properties from the groove 141 into the groove 141, the temperature of the center C of the substrate W may be variably controlled. The temperature of the center C of the substrate W may be more precisely controlled according to the physical properties, diameter, and thickness of the plate 143. The thermal conductivity of the plate 143 may vary according to the physical properties, diameter, and thickness thereof. The temperature transmitted to the substrate W may be controlled by replacing the plate 143 having different physical properties, diameters, or thicknesses and arranging the replaced plate 143 inside the groove 141. As a result, by variably controlling the temperature of the center C of the substrate W, the temperature of the center C of the substrate W and the temperature deviation at an edge E of the substrate W may be more precisely controlled.

In one or more embodiments, the temperature of the center portion of the substrate W may be changed by using a change in thermal conduction according to the physical properties of the plate 143. For example, when the thickness of the plate 143 increases or a material having relatively high thermal conductivity is used, the temperature of the center of the substrate W may be increased.

In one or more embodiments, the satellite disk 14 may use a material that forms a SiC coating layer on graphite having a thermal conductivity of about 273 W/mk. In addition, the plate 143 may include a diamond material having a thermal conductivity of about 2200 W/mk, which is about 10 times higher than that of the satellite disk 14. By arranging the plate 143 having a higher thermal conductivity than the satellite disk 14 in the groove 141, the temperature of the center portion of the substrate W may be increased.

In one or more embodiments, the plate 143 of the chemical vapor deposition apparatus 1 according to one or more embodiments may be configured to be detachably attached to the groove 141. The plate 143 having a different size and physical properties may be replaced and arranged in the groove 141 according to process conditions. For example, when the temperature of the center portion of the substrate W is relatively low compared to the temperature of the edge portion of the substrate W, the plate 143 may be replaced with a plate having high thermal conductivity and arranged in the groove 141.

In one or more embodiments, by replacing the plate 143 having a different size and physical properties as needed and arranging in the groove 141, wavelength control may be more precisely performed, and process cost may be reduced compared to changing the entire facility. In this case, according to a change in the first thickness h₁ of the groove 141, the second thickness h₂ of the plate 143 may be variably designed.

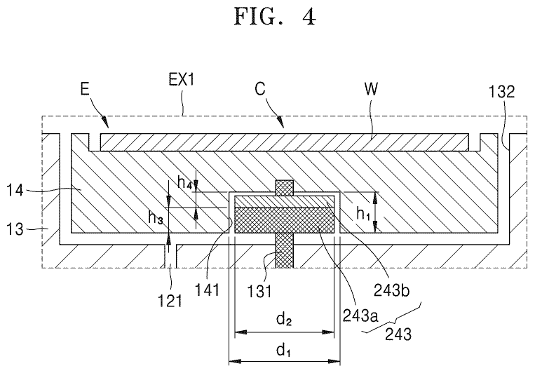

FIG. 4 is an enlarged cross-sectional view of region EX1 in FIG. 1 according to one or more other embodiments.

In a chemical vapor deposition apparatus of FIG. 4, except for the configuration of a plate 243, the configuration of the chemical vapor deposition apparatus 1 described with reference to FIGS. 1 through 3 is substantially the same, and thus differences are mainly described.

Referring to FIG. 4, the plate 243 may include a first plate 243a and a second plate 243b. Although FIG. 4 illustrates that the plate 243 includes two plates (243a and 243b), embodiments are not limited thereto.

In one or more embodiments, the first plate 243a and the second plate 243b may be arranged to be inserted into the groove 141. Each of the first plate 243a and the second plate 243b may include a through hole, and the fixing pin 131 may penetrate the through hole. The fixing pin 131 may fix the first plate 243a and the second plate 243b to be seated in the groove 141 of the satellite disk 14. In this case, the diameter of the through hole and the diameter of the fixing pin 131 may be the same. The diameter of the through hole and the diameter of the fixing pin 131 may be about 2.5 mm.

In one or more embodiments, the first plate 243a may include a first material having a first property, and the second plate 243b may include a second material having a second property that may be different from the first property. In this case, the second material may include a material having a thermal conductivity that is different from a thermal conductivity of the first material, but embodiments are not limited thereto. For example, the first material may include SiC, and the second material may include diamond (C).

In one or more embodiments, the first plate 243a may have a third thickness h₃, and the second plate 243b may have a fourth thickness h4. In this case, a sum of the third thickness h₃ and the fourth thickness h₄ may be less than the first thickness h1. For example, the sum of the third thickness h₃ and the fourth thickness h₄ may be about 0.2 mm to about 0.4 mm, but embodiments are not limited thereto.

In one or more embodiments, the first plate 243a and the second plate 243b may each have a second diameter d₂. In addition, the second diameter d₂ may be less than the first diameter d₁. For example, the second diameter d₂ may be about 38 mm, but embodiments are not limited thereto. For example, the first plate 243a and the second plate 243b may also have different diameters. In this case, a certain space may be formed between the plate 243 and the groove 141.

The chemical vapor deposition apparatus 1 according to one or more embodiments may variably control the temperature of the substrate W, by variously controlling the plate 243 inserted into and arranged in the groove 141. In particular, by inserting and arranging the first plate 243a and the second plate 243b having different sizes and physical properties into the groove 141, the temperature of the center C of the substrate W may be variably controlled. The temperature of the center C of the substrate W may be precisely controlled according to the physical properties, diameters, and thicknesses of the first plate 243a and the second plate 243b. In this case, only the first plate 243a or the second plate 243b may be selectively replaced and arranged.

The thermal conductivity of the plate 243 may vary according to the physical properties, diameters, and thicknesses of the first plate 243a and the second plate 243b. The temperature transmitted to the substrate W may be controlled by replacing the plate 243 having different physical properties, diameters, or thicknesses and arranging the replaced plate 243 inside the groove 141. As a result, by variably controlling the temperature of the center C of the substrate W, the temperature of the center C of the substrate W and the temperature deviation at an edge E of the substrate W may be more precisely controlled.

In one or more embodiments, the temperature of the center portion of the substrate W may be changed by using a change in thermal conduction according to the physical properties of the plate 243. For example, when the thickness of the plate 243 increases or a material having relatively high thermal conductivity is used, the temperature of the center of the substrate W may be increased. In one or more embodiments, the plate 243 of the chemical vapor deposition apparatus 1 according to one or more embodiments may be configured to be detachably attached to the groove 141. The plate 243 having a different size and physical properties may be replaced and arranged in the groove 141 according to process conditions. For example, when the temperature of the center portion of the substrate W is relatively low compared to the temperature of the edge portion of the substrate W, the plate 143 may be replaced with a plate having high thermal conductivity and arranged in the groove 141. In this case, only the first plate 243a may be replaced, only the second plate 243b may be replaced, or the first plate 243a and the second plate 243b may be replaced together.

In one or more embodiments, by replacing the plate 243 having a different size and physical properties as needed and arranging in the groove 141, wavelength control may be precisely performed, and process cost may be reduced compared to changing the entire facility. In this case, according to a change in the first thickness h₁ of the groove 141, the second thickness h₂ of the plate 243 may be variably designed.

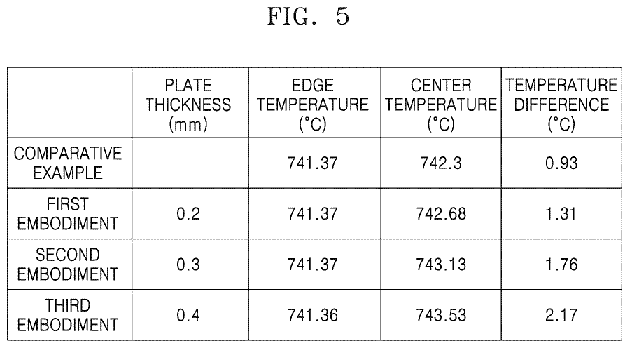

FIG. 5 is a table showing a temperature of a substrate with respect to a plate thickness of the chemical vapor deposition apparatus 1, according to one or more embodiments.

Referring to FIGS. 1 and 5, in the chemical vapor deposition apparatus 1 according to one or more embodiments, it may be identified that the temperature of the center (refer to C in FIG. 3) and the temperature of the edge (refer to E in FIG. 3) of the substrate W change according to the thickness of the plate 143. In this case, the plate 143 may include SiC.

The related example uses a conventional chemical vapor deposition apparatus without a plate, and in this case, it may be identified that the edge temperature of the substrate W is about 741.37° C. and the center temperature of the substrate W is about 742.3° C. Accordingly, it may be identified that the difference between the edge temperature of the substrate and the center temperature of the substrate is about 0.93° C.

A first embodiment may be the chemical vapor deposition apparatus 1 according to one or more embodiments, in which the second thickness h₂ of the plate 143 is about 0.2 mm. In this case, it may be identified that the center C temperature of the substrate W is about 741.37° C. and the edge E temperature of the substrate W is about 742.68° C. Accordingly, it may be identified that the difference between the temperature of the edge E of the substrate W and the temperature of the center C of the substrate W is about 1.31° C.

A second embodiment may be the chemical vapor deposition apparatus 1 according to one or more embodiments, in which the second thickness h₂ of the plate 143 is about 0.3 mm. In this case, it may be identified that the center C temperature of the substrate W is about 741.37° C. and the edge E temperature of the substrate W is about 743.13° C. Accordingly, it may be identified that the difference between the temperature of the edge E of the substrate W and the temperature of the center C of the substrate W is about 1.76° C.

A third embodiment may be the chemical vapor deposition apparatus 1 according to one or more embodiments, in which the second thickness h₂ of the plate 143 is about 0.4 mm. In this case, it may be identified that the center C temperature of the substrate W is about 741.36° C. and the edge E temperature of the substrate W is about 743.53° C. Accordingly, it may be identified that the difference between the temperature of the edge E of the substrate W and the temperature of the center C of the substrate W is about 2.17° C.

In the three embodiments, it may be identified that as the thickness of the plate 143 increases, the temperature of the edge E of the substrate W is constant, but the temperature of the center C of the substrate W increases. Thus, as the thickness of the plate 143 increases, the difference between the temperature of the edge E of the substrate W and the temperature of the center C of the substrate W may increase.

The chemical vapor deposition apparatus 1 according to one or more embodiments may compensate for the temperature of the center C of the substrate W, by forming a groove 141 at the center of the lower surface of the satellite disk 14 and inserting and arranging the plate 143 into the groove 141. By compensating for the temperature of the center C of the substrate W, the non-uniformity in the thickness and wavelength of the growth layer grown on the substrate W may be reduced, and thus, by making the light emitting wavelength and electrical characteristics of the light emitting device uniform, the quality, performance, and yield of the substrate W may be increased.

In addition, by replacing and arranging the plate 143 having a different size and physical properties into the groove 141, the temperature of the center C of the substrate W may be variably controlled. Because the thermal conductivity of the plate 143 changes according to the physical properties, diameter, and thickness of the plate 143, the temperature of the center C of the substrate W may be more precisely controlled. As a result, by variably controlling the temperature of the center C of the substrate W, the temperature of the center C of the substrate W and the temperature deviation at an edge E of the substrate W may be precisely controlled.

While embodiments have been described with reference to the figures, it will be understood by those of ordinary skill in the art that various changes in form and details may be made therein without departing from the spirit and scope as defined by the following claims and their equivalents.

What is claimed is:

1. A chemical vapor deposition apparatus comprising:
a reaction chamber;
a main disk inside the reaction chamber;
a satellite disk on the main disk, a lower surface of the satellite disk comprising a groove that has a first thickness and a first diameter;
a plate in the groove; and
a fixing pin configured to penetrate the plate and connected to the main disk and the satellite disk.

2. The chemical vapor deposition apparatus of claim 1, wherein the groove is at a center portion of the lower surface of the satellite disk and concentric with the satellite disk.

3. The chemical vapor deposition apparatus of claim 1, wherein a second thickness of the plate is less than the first thickness, and
wherein a second diameter of the plate is less than the first diameter.

4. The chemical vapor deposition apparatus of claim 1, wherein the plate comprises a through hole, and
wherein a diameter of the through hole is equal to a diameter of the fixing pin.

5. The chemical vapor deposition apparatus of claim 1, wherein the plate comprises a first plate and a second plate, and
wherein a thermal conductivity of the first plate is different from a thermal conductivity of the second plate.

6. The chemical vapor deposition apparatus of claim 5, wherein the first plate has a third thickness and a third diameter, and
wherein the second plate has a fourth thickness and a fourth diameter.

7. The chemical vapor deposition apparatus of claim 1, wherein the plate includes silicon carbide.

8. The chemical vapor deposition apparatus of claim 1, wherein the first thickness is less than a thickness of the satellite disk.

9. The chemical vapor deposition apparatus of claim 1, wherein a thermal conductivity of the plate is greater than a thermal conductivity of the satellite disk.

10. A chemical vapor deposition apparatus comprising:
a reaction chamber;
a main disk in the reaction chamber and comprising a pocket;
a satellite disk, a center portion of a lower surface of the satellite disk comprising a groove having a first thickness and a first diameter, the satellite disk being in the pocket;
a fixing pin between the main disk to the satellite disk; and
a plate comprising a through hole having a diameter equal to a diameter of the fixing pin, the plate being detachably inserted in the groove,
wherein a second thickness of the plate is less than the first thickness and a second diameter of the plate is less than the first diameter.

11. The chemical vapor deposition apparatus of claim 10, wherein the plate includes silicon carbide.

12. The chemical vapor deposition apparatus of claim 10, wherein the plate comprises a first plate and a second plate, and
wherein a thermal conductivity of the first plate is different from a thermal conductivity of the second plate.

13. The chemical vapor deposition apparatus of claim 12, wherein the first plate has a third thickness and a third diameter, and
wherein the second plate has a fourth thickness and a fourth diameter.

14. The chemical vapor deposition apparatus of claim 10, wherein a thermal conductivity of the plate is greater than a thermal conductivity of the satellite disk.

15. A chemical vapor deposition apparatus comprising:
a reaction chamber;
a main disk inside the reaction chamber and comprising a pocket;
a satellite disk inside the pocket and configured to rotate, the satellite disk being configured to accommodate a substrate and comprising a groove having a first thickness and a first diameter in a lower surface of the satellite disk;
a gas inlet configured to supply a reaction gas to the substrate;
a support unit comprising a gas flow path through which a flow gas is supplied to the pocket, the gas flow path being configured to support the main disk to be rotatable;
a fixing pin between the main disk and the satellite disk; and
a plate penetrated by the fixing pin, and inserted into the groove,
wherein a second thickness of the plate is less than the first thickness and a second diameter of the plate is less than the first diameter.

16. The chemical vapor deposition apparatus of claim 15, wherein the groove is at a center portion of the lower surface of the satellite disk and concentric to the satellite disk.

17. The chemical vapor deposition apparatus of claim 15, wherein the plate includes silicon carbide.

18. The chemical vapor deposition apparatus of claim 15, wherein the plate comprises a first plate and a second plate, and
wherein a thermal conductivity of the first plate is different from a thermal conductivity of the second plate.

19. The chemical vapor deposition apparatus of claim 18, wherein the first plate has a third thickness and a third diameter, and
wherein the second plate has a fourth thickness and a fourth diameter.

20. The chemical vapor deposition apparatus of claim 14, wherein thermal conductivity of the plate is greater than thermal conductivity of the satellite disk.
